(19) United States
(12) Patent Application Publication
(10) Pub. No.: US 2026/0206511 A1
(43) Pub. Date: Jul. 16, 2026

(54) COMPOSITION FOR PHOTORESIST REMOVAL AND METHOD FOR REMOVING PHOTORESIST

(71) Applicant: MITSUBISHI GAS CHEMICAL COMPANY, INC., Tokyo (JP)

(72) Inventors: Shin-ya KUROSAWA, Kanagawa (JP); Takashi SUGIMOTO, Kanagawa (JP); Masami SONE, Kanagawa (JP); Satoshi TAMAI, Kanagawa (JP); Yoshiki MIYASHITA, Kanagawa (JP)

(73) Assignee: MITSUBISHI GAS CHEMICAL COMPANY, INC., Tokyo (JP)

(21) Appl. No.: 19/137,354

(22) PCT Filed: Dec. 12, 2023
(86) PCT No.: PCT/JP2023/044368

§ 371 Date: Jun. 10, 2025

(30) Foreign Application Priority Data
Dec. 12, 2022 (JP) 2022-198230

(51) Int. Cl. H10P 50/68; C11D 3/04; C11D 3/28; C11D 3/30; H10P 14/47; H10W 70/05

(52) U.S. Cl. CPC H10P 50/68; C11D 3/042; C11D 3/28; C11D 3/30; H10P 14/47; H10W 70/05

(57) ABSTRACT

The present invention can provide a composition for removing a photoresist, which is for forming a copper-containing pattern, after the pattern has been formed, including: an alkaline agent; and an azole compound, wherein the alkaline agent is one or more selected from the group consisting of an alkanolamine, a quaternary ammonium hydroxide, and an inorganic alkali, the azole compound is one or more selected from the group consisting of compounds represented by the following formulas (1) to (3), and the composition has a pH of 10 or higher,

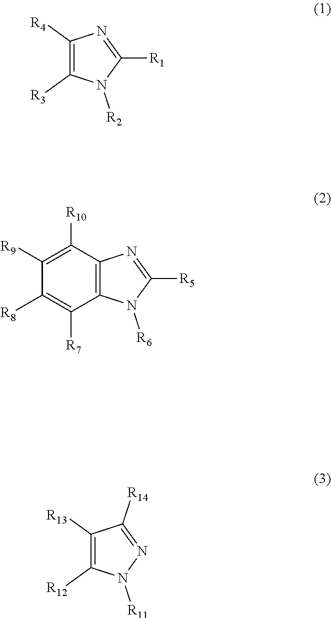

wherein R₁ to R₁₄ each independently represent a hydrogen atom, an optionally substituted alkyl group having 1 or more and 7 or less carbon atoms, or an optionally substituted amino group.

### TECHNICAL FIELD

The present invention relates to a composition for photoresist removal and a method for removing a photoresist using the same and so on.

### BACKGROUND ART

In recent years, electronic devices are becoming smaller and more functional, and the printed wiring boards used in such electronic devices are also required to become smaller and more functional.

In order to produce a printed wiring board and the like that satisfies such a demand, a method such as the following is adopted. For example, a metal layer called a seed layer is formed on an insulating layer that contains copper wiring in a portion thereof. A photoresist layer is formed on the surface of the seed layer, and the photoresist is exposed and developed to form a resist pattern. Then, copper plating is applied to the openings of the pattern, and the photoresist and seed layer are then removed to form a circuit pattern that serves as a connection terminal portion of the copper wiring.

As described above, methods for producing a printed wiring board and the like often include a step of removing a photoresist, and in the photoresist removal step, an aqueous solution containing various components is usually used (for example, Patent Literature 1).

### CITATION LIST

### Patent Literature

Patent Literature 1: International Publication No. 2020/022491

### SUMMARY OF INVENTION

### Technical Problem

In the conventional step of removing a photoresist, if a conventional processing solution is used, particularly a highly reactive processing solution for efficiently removing the photoresist, there is a possibility that copper-containing members such as the copper plating may be damaged. Further, for example, a residue of the processing solution for removing the photoresist may have an adverse effect on the copper-containing members.

In light of the above, there is a need for a technique that is excellent in protecting copper-containing members and does not leave a residue that adheres to the photoresist during photoresist removal, which is a part of the production process for printed wiring boards and the like.

### Solution to Problem

The present invention includes, for example, the following aspects.

[1] A composition for removing a photoresist, which is for forming a copper-containing pattern, after the pattern has been formed, including:
an alkaline agent; and
an azole compound, wherein
the alkaline agent is one or more selected from the group consisting of an alkanolamine, a quaternary ammonium hydroxide, and an inorganic alkali,
the azole compound is one or more selected from the group consisting of compounds represented by the following formulas (1) to (3), and
the composition has a pH of 10 or higher,

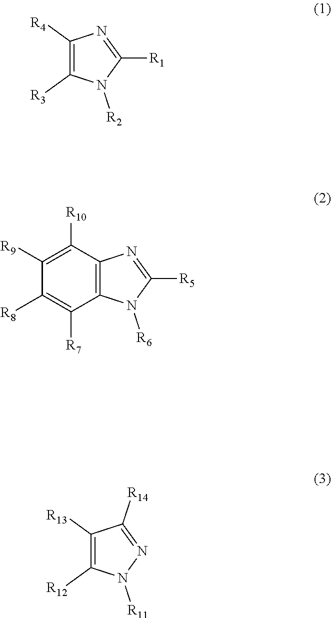

wherein R₁ to R₁₄ each independently represent a hydrogen atom, an optionally substituted alkyl group having 1 or more and 7 or less carbon atoms, or an optionally substituted amino group.
   [2] The composition according to the above [1], wherein an etching rate of copper is less than 0.05 μm/min.
   [3] The composition according to the above [1], wherein the azole compound includes at least any of 4-methylimidazole, 2-methylimidazole, 5-methylbenzimidazole, 2-aminobenzimidazole, and 3-methylpyrazole.
   [4] The composition according to the above [1], further including an organic solvent.
   [5] The composition according to the above [1], wherein the composition includes, based on a total amount of the composition, 3.0 to 50% by mass of the alkaline agent and 0.001 to 1.0% by mass of the azole compound.
   [6] The composition according to the above [1], wherein the composition is water-soluble.
   [7] The composition according to the above [1], wherein the composition is free from a thiol compound.
   [8] The composition according to the above [1], wherein the pattern is a circuit pattern that serves as a connection terminal portion of copper wiring formed on an insulating layer having the copper wiring in at least a part thereof.
   [9] A method for removing a photoresist, including a photoresist removal step of bringing the composition according to any of the above [1] to [8] into contact with a photoresist for forming a copper-containing pattern.
   [10] The method for removing a photoresist according to the above [9], wherein the pattern is a circuit pattern that serves as a connection terminal portion of copper wiring formed on an insulating layer having the copper wiring in at least a part thereof.
   [11] A method for producing a printed wiring board, a semiconductor element, or a semiconductor package, including a photoresist removal step of bringing the composition according to any of the above [1] to [8] into contact with a photoresist for forming a copper-containing pattern.
   [12] The method for producing a printed wiring board, a semiconductor element, or a semiconductor package according to the above [11], further including, after the photoresist removal step, a cleaning step of cleaning a photoresist-containing substrate that contained the photoresist.
   [13] The method for producing a printed wiring board, a semiconductor element, or a semiconductor package according to the above [12], wherein in the cleaning step, the photoresist-containing substrate is cleaned using sulfuric acid having a concentration of 40% by mass or less and/or water.
   [14] The method for producing a printed wiring board, a semiconductor element, or a semiconductor package according to the above [11], wherein the pattern is a circuit pattern that serves as a connection terminal portion of copper wiring formed on an insulating layer having the copper wiring in at least a part thereof.

### Advantageous Effects of Invention

According to the present invention, a composition for photoresist removal that is excellent in protecting copper-containing members and the like while efficiently removing the photoresist and does not leave a residue on the surface of the photoresist, and so on are provided.

### DESCRIPTION OF EMBODIMENTS

The composition of the present invention can be preferably used, for example, to remove a photoresist after the formation of a copper-containing pattern, and contains at least a specific alkaline agent and azole compound. The composition will now be described in detail below.

### [I. Composition]

The composition is preferably water-soluble. That is, it is preferred that at least a part of the composition can dissolve or is suspendable in water, and it is more preferred that the composition can be uniformly mixed with water in any ratio.

In addition, it is preferred that at least a part of the components other than water contained in the composition can dissolve in water, and it is more preferred that the components other than water contained in the composition and water can be mixed uniformly.

### <I-1. (A) Alkaline Agent>

The composition preferably contains 3.0 to 50% by mass of an alkaline agent (A) (hereinafter also referred to as component (A)) based on the total mass of the composition. The content of the alkaline agent in the composition is, based on the total mass of the composition, more preferably 4.0 to 40% by mass, further preferably 5.0 to 30% by mass or 6.0 to 35% by mass, and particularly preferably 7.0 to 15% by mass, 8.0 to 20% by mass, or 9.0 to 12% by mass.

A composition containing the component (A) can have effects such as good removability of the photoresist and suppressed damage to a circuit pattern that includes copper, a copper alloy, or the like, which serves as a connection terminal portion of the copper wiring.

The alkaline agent (A) preferably contains any selected from (A-1) an alkanolamine, (A-2) a quaternary ammonium hydroxide, and (A-3) an inorganic alkali, more preferably contains two of these, and particularly preferably contains all of (A-1) to (A-3).

### (A-1) Alkanolamine

The type of the (A-1)alkanolamine that may be contained in the composition as the component (A) is not particularly limited, and examples may include a monoalkanolamine, a dialkanolamine, a trialkanolamine, or an alkylated product (N-alkylated product, O-alkylated product) thereof.

Preferred examples of the alkanolamine (A) include 2-aminoethanol (monoethanolamine), N-methylethanolamine, N-ethylethanolamine, N-propylethanolamine, N-butylethanolamine, diethanolamine, 1-amino-2-propanol (isopropanolamine), N-methylisopropanolamine, N-ethylisopropanolamine, N-propylisopropanolamine, 2-aminopropan-1-ol, N-methyl-2-amino-propan-1-ol, N-ethyl-2-amino-propan-1-ol, 1-aminopropan-3-ol, N-methyl-1-aminopropan-3-ol, N-ethyl-1-aminopropan-3-ol, 1-aminobutan-2-ol, N-methyl-1-aminobutan-2-ol, N-ethyl-1-aminobutan-2-ol, 2-aminobutan-1-ol, N-methyl-2-aminobutan-1-ol, N-ethyl-2-aminobutan-1-ol, 3-aminobutan-1-ol, N-methyl-3-aminobutan-1-ol, N-ethyl-3-aminobutan-1-ol, 1-aminobutan-4-ol, N-methyl-1-aminobutan-4-ol, N-ethyl-1-aminobutan-4-ol, 1-amino-2-methylpropan-2-ol, 2-amino-2-methylpropan-1-ol, 1-aminopentan-4-ol, 2-amino-4-methylpentan-1-ol, 2-aminohexane-1-ol, 3-aminoheptan-4-ol, 1-aminooctan-2-ol, 5-aminooctan-4-ol, 1-aminopropane-2,3-diol, 2-aminopropane-1,3-diol, tris(oxymethyl)aminomethane, 1,2-diaminopropan-3-ol, 1,3-diaminopropan-2-ol, 2-(2-aminoethoxy)ethanol, and the like. These may be used alone or in combination of two or more.

Among these, the alkanolamine is preferably one or more selected from the group consisting of 2-aminoethanol (monoethanolamine) and 1-amino-2-propanol.

The content of the alkanolamine is, based on the total amount of the composition, preferably 1.0 to 50% by mass, more preferably 1.5 to 45% by mass, 1.5 to 42% by mass, 2.0 to 30% by mass or 2.0 to 15% by mass, further preferably 3.0 to 12% by mass, and particularly preferably 4.0 to 8.0% by mass or 5.0 to 9.0% by mass.

### (A-2) Quaternary Ammonium Hydroxide

The type of the (A-2) quaternary ammonium hydroxide that may be contained in the composition as the component (A) is not particularly limited, and examples include tetramethylammonium hydroxide, tetraethylammonium hydroxide, tetrapropylammonium hydroxide, triethylmethylammonium hydroxide, ethyltrimethylammonium hydroxide, trimethyl(2-hydroxyethyl) ammonium hydroxide, and triethyl(2-hydroxyethyl) ammonium hydroxide. These may be used alone or in combination of two or more.

Among these, the quaternary ammonium hydroxide is preferably one or more selected from the group consisting of tetramethylammonium hydroxide, tetraethylammonium hydroxide, and triethylmethylammonium hydroxide.

The content of the quaternary ammonium hydroxide is, based on the total amount of the composition, preferably 0.3 to 10% by mass, more preferably 0.5 to 8.0% by mass, further preferably 0.7 to 9.0% by mass, and particularly preferably 0.8 to 4.0% by mass or 0.9 to 5.0% by mass.

### (A-3) Inorganic Alkali

The type of the inorganic alkali (A-3) that may be contained in the composition as the component (A) is not particularly limited, and examples include an alkali metal compound such as lithium hydroxide, sodium hydroxide, potassium hydroxide, sodium carbonate, potassium carbonate, sodium silicate, and potassium silicate; an alkaline earth metal compound such as magnesium hydroxide, calcium hydroxide, magnesium carbonate, calcium carbonate, calcium silicate, and magnesium silicate; a transition metal compound such as copper hydroxide and iron hydroxide; ammonia, and the like.

Of these, potassium hydroxide, sodium hydroxide, and the like are preferred as the inorganic alkali.

The content of the inorganic alkali is preferably, based on the total amount of the composition, 0.001 to 5.0% by mass, more preferably 0.01 to 3.0% by mass, further preferably 0.05 to 2.0% by mass, and particularly preferably 0.1 to 0.5% by mass or 0.2 to 1.0% by mass.

### <I-2. (B) Azole Compound>

The composition preferably contains 0.001 to 1.0% by mass of the (B) azole compound (hereinafter also referred to as component (B)) based on the total mass of the composition. The content of the azole compound in the composition is, based on the total mass of the composition, more preferably 0.005 to 0.80% by mass, further preferably 0.01 to 0.50% by mass or 0.02 to 0.60% by mass, and particularly preferably 0.02 to 0.40% by mass, 0.02 to 0.30% by mass, 0.25 to 0.40% by mass, 0.25 to 0.30% by mass, or 0.03 to 0.20% by mass.

A composition containing the component (B) can have effects such as protecting a metal layer containing copper or a copper alloy and reducing the etching rate of copper.

The azole compound in the composition preferably contains at least any of an imidazole compound, a benzimidazole compound, and a pyrazole compound.

### (B-1) Imidazole Compound

The imidazole compound is not particularly limited as long as it has an imidazole ring, but it is preferred to use a compound having the following formula (1) as at least one component of the composition.

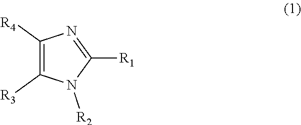

In formula (1), R₁ to R₄ are each independently selected from a hydrogen atom, an optionally substituted alkyl group having 1 or more and 7 or less carbon atoms, and an optionally substituted amino group.

The number of carbon atoms in the alkyl group is preferably 1 or more and 5 or less, more preferably 1 or more and 3 or less, and further preferably 1 or 2, or 1.

Examples of the above-described substituent include a hydroxyl group, a halogen, a vinyl group, a carboxyl group, a cyano group, a nitro group, a (meth)acryloxy group, a glycidyloxy group, a mercapto group, an amino group, and the like. When any of R₁ to R₄ is an alkyl group, the substituent may be an amino group, for example, an amino group which may contain an alkyl group having 10 or less carbon atoms. When any of R₁ to R₄ is an amino group, the substituent may be an alkyl group, for example, an alkyl group having 10 or less carbon atoms.

When an alkyl group or amino group having a substituent is contained in the imidazole compound of formula (1), the above-described number of carbons is the total number of carbon atoms including the carbons of the substituent.

Preferred specific examples of the imidazole compound include imidazole and imidazole derivatives having the above-described substituents, for example, a 1-alkylimidazole such as 1-methylimidazole, a 2-alkylimidazole such as 2-methylimidazole, a 4-alkylimidazole such as 4-methylimidazole, imidazolium salts of these, and the like.

### (B-2) Benzimidazole Compound

The benzimidazole compound is not particularly limited as long as it has a benzimidazole skeleton, but it is preferred to use a compound having the following formula (2) as at least one component of the composition.

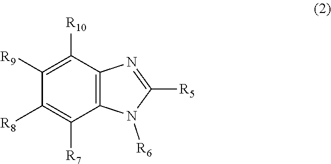

In formula (2), R₅ to R₁₀ are each independently selected from a hydrogen atom, an optionally substituted alkyl group having 1 or more and 7 or less carbon atoms, and an optionally substituted amino group.

The number of carbon atoms in the alkyl group is preferably 1 or more and 5 or less, more preferably 1 or more and 3 or less, and further preferably 1 or 2, or 1.

Examples of the substituent include a hydroxyl group, a halogen, a vinyl group, a carboxyl group, a cyano group, a nitro group, a (meth)acryloxy group, a glycidyloxy group, a mercapto group, an amino group, and the like. When any of R₅ to R₁₀ is an alkyl group, the substituent may be an amino group, for example, an amino group which may contain an alkyl group having 10 or less carbon atoms. When any of R₅ to R₁₀ is an amino group, the substituent may be an alkyl group, for example, an alkyl group having 10 or less carbon atoms.

When an alkyl group or amino group having a substituent is contained in the benzimidazole compound of formula (2), the above-described number of carbons is the total number of carbon atoms including the carbons of the substituent.

Preferred specific examples of the benzimidazole compound include benzimidazole and benzimidazole derivatives having the above-described substituents, for example, a 1-alkylbenzimidazole such as 1-methylbenzimidazole, a 2-alkylbenzimidazole such as 2-methylbenzimidazole, a 5-alkylbenzimidazole such as 5-methylbenzimidazole, 1-aminobenzimidazole, 2-aminobenzimidazole, 5-aminobenzimidazole, benzimidazolium salts of these, and the like.

### (B-3) Pyrazole Compound

The pyrazole compound is not particularly limited as long as it has a pyrazole ring, but it is preferred to use a compound having the following formula (3) as at least one component of the composition.

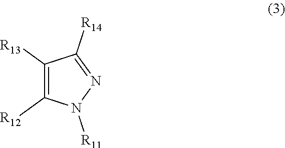

In formula (3), R₁₁ to R₁₄ are each independently selected from a hydrogen atom, an optionally substituted alkyl group having 1 or more and 7 or less carbon atoms, and an optionally substituted amino group.

The number of carbon atoms in the alkyl group is preferably 1 or more and 5 or less, more preferably 1 or more and 3 or less, and further preferably 1 or 2, or 1.

Examples of the above-described substituent include a hydroxyl group, a halogen, a vinyl group, a carboxyl group, a cyano group, a nitro group, a (meth)acryloxy group, a glycidyloxy group, a mercapto group, an amino group, and the like. When any of R₁₁ to R₁₄ is an alkyl group, the substituent may be an amino group, for example, an amino group which may contain an alkyl group having 10 or less carbon atoms. When any of R₁₁ to R₁₄ is an amino group, the substituent may be an alkyl group, for example, an alkyl group having 10 or less carbon atoms.

When an alkyl group or amino group having a substituent is contained in the pyrazole compound of formula (3), the above-described number of carbons is the total number of carbon atoms including the carbons of the substituent.

Preferred specific examples of the pyrazole compound include pyrazole and pyrazoles having the above-described substituents, for example, a 1-alkylpyrazole such as 1-methylpyrazole, a 3-alkylpyrazole such as 3-methylpyrazole, a 4-alkylpyrazole such as 4-methylpyrazole, a 5-alkylpyrazole such as 5-methylpyrazole, and pyrazole salts of these.

### <I-3. Water>

The composition preferably contains water. There are no particular limitations on the type of water contained in the composition, but it is preferred that metal ions, organic impurities, particles, and the like have been removed by, for example, distillation, an ion exchange treatment, filtration, or some kind of adsorption treatment. It is more preferred to use pure water, and particularly preferred to use ultrapure water.

The water content in the composition is, based on the total amount of the composition, preferably 20% by mass or more, more preferably more than 20% by mass, and more preferably in the range of 20 to 99% by mass, further preferably 50 to 97% by mass, still further preferably 60 to 95% by mass, and particularly preferably 70 to 95% by mass. In a composition in which the water content has been adjusted in this way, reactivity with the photoresist and removability of the photoresist are improved.

### <I-4. Other Components>

The composition may contain other components as necessary, as long as the components do not impair the above-described effects. Examples of other components include a solvent, an ammonium salt, a pH adjuster, a surfactant, a defoamer, and the like.

Further, carbonate ions, or a carbonate, bicarbonate, and the like that generates carbonate ions, may be added to the composition. Adding carbonate ions and the like to the composition improves copper corrosion protection. Specific examples of the carbonate or bicarbonate include salts of ammonium ions, salts of alkali metals or alkaline earth metals, and the like, and an ammonium carbonate such as tetramethylammonium carbonate may be added to the composition.

The content of secondary components in the composition is, based on the total amount of the composition, preferably 10% by mass or less, more preferably 5.0% by mass or less, more preferably 3.0% by mass or less, further preferably 2.0% by mass or less, or 1.5% by mass or less.

Further, the content of each salt component that generates carbonate ions in the composition is preferably 5.0% by mass or less, more preferably 3.0% by mass or less, further preferably 2.0% by mass or less, or 1.5% by mass or less.

In addition, the composition is preferably a solution, and preferably does not contain solid particles such as abrasive particles.

It is preferred to add an organic solvent, such as an ether compound or an alcohol, to the composition. By using a specific solvent, the solubility of the photoresist in the composition is improved, and there is found to be an effect of enhancing removability.

Of the preferred organic solvents, specific examples of the ether include ethylene glycol monomethyl ether, ethylene glycol monoethyl ether, ethylene glycol monopropyl ether, ethylene glycol monoisopropyl ether, ethylene glycol monobutyl ether, ethylene glycol monohexyl ether, diethylene glycol monomethyl ether, triethylene glycol monomethyl ether, diethylene glycol monoethyl ether, triethylene glycol monoethyl ether, diethylene glycol monobutyl ether, triethylene glycol monobutyl ether, phenyl glycol=ethylene glycol monophenyl ether, diethylene glycol monophenyl ether, and the like.

Of the preferred organic solvents, specific examples of the alcohol include an aromatic alcohol such as benzyl alcohol, salicyl alcohol, anisyl alcohol, anise alcohol, gentisyl alcohol, protocatechuyl alcohol, vanillyl alcohol, veratryl alcohol, syringyl alcohol, cuminyl alcohol, phenethyl alcohol, and the like.

The content of the solvent is, based on the total amount of the composition, preferably 0.01 to 20% by mass, more preferably 0.1 to 10% by mass, further preferably 0.2 to 5.0% by mass, and particularly preferably 0.3 to 3.5% by mass or 0.4 to 4.0% by mass.

The composition preferably contains an ammonium ion source, such as an ammonium salt, for example a quaternary ammonium salt. The use of a specific ammonium ion source can have the effect of enhancing the removability of the photoresist.

The type of the ammonium ion source that can be included in the composition is not particularly limited, and examples include ammonia, an ammonium salt such as an ammonium halide salt (ammonium chloride, ammonium bromide, ammonium iodide, and the like), an ammonium salt of an organic acid, an ammonium salt of an inorganic acid, and the like. As the ammonium ion source, an ammonium salt of an organic acid is preferred. Examples of the ammonium salt of an organic acid include an ammonium salt of an aromatic organic acid, an ammonium salt of a fatty acid, and the like.

Examples of the ammonium salt of an aromatic organic acid include a mono-, di-, or tri-ammonium salt of an aromatic carboxylic acid having from 6 to 30 carbon atoms. Specific examples include an ammonium salt of benzoic acid, phthalic acid, salicylic acid, and the like, that is, ammonium benzoate, ammonium (di)phthalate, ammonium salicylate, and the like.

Further, examples of the ammonium salt of a fatty acid include a mono-, di-, or tri-ammonium salt of a saturated or unsaturated fatty acid having from 1 to 20 carbon atoms. Specific examples include an ammonium salt of: a saturated fatty acid such as formic acid, acetic acid, propionic acid, butyric acid, valeric acid, lauric acid, tridecylic acid, palmitic acid, and stearic acid; and an unsaturated fatty acid such as acrylic acid, methacrylic acid, oleic acid, linoleic acid, and linolenic acid; and the like.

As the ammonium ion source, one type may be used, or two or more types may be used. It is preferred that the composition contains, based on the total amount of the ammonium ion source in the composition, 30% by mass or more of the aromatic organic acid ammonium salt or fatty acid ammonium salt, more preferably 50% by mass or more of the aromatic organic acid ammonium salt or fatty acid ammonium salt, further preferably 70% by mass or more of the aromatic organic acid ammonium salt or fatty acid ammonium salt, and particularly preferably 90% by mass or more of the aromatic organic acid ammonium salt or fatty acid ammonium salt. It is even still more preferred for the composition to contain only the aromatic organic acid ammonium salt or fatty acid ammonium salt as the ammonium ion source.

The content of the ammonium ion source is, based on the total mass of the composition, preferably 0.1 to 20% by mass. The content of the ammonium ion source in the composition is more preferably 0.15 to 10% by mass based on the total mass of the composition, further preferably 0.20 to 5.0% by mass, and particularly preferably 0.25 to 2.5% by mass, 0.50 to 3.0% by mass, or 1.0 to 2.0% by mass.

There are also some components that are preferably not added to the composition. Examples of undesirable components in the composition include thiols, organic acids containing a sulfur atom, chelating agents, and the like.

If the photoresist is removed using a composition containing a chelating agent, the residual chelating agent may have an adverse effect in the subsequent flash etching process in which copper is etched. This is because if the chelating agent adheres to the copper surface, the chelating agent may interfere with the etching process.

Further, when an organic acid containing a sulfur atom is used as a component of the composition, an odor may be produced by the sulfur-containing compound, and the stability of the composition may decrease.

Therefore, it is preferred that the composition of the present invention does not contain the above-described compounds.

### <I-5. Method for Preparing the Composition>

The composition of the present invention is prepared by adding the component (A), the component (B), water, and, if necessary, other components, and stirring preferably until the mixture becomes completely uniform. In producing the composition, the order of adding and mixing each component is not particularly limited. For example, a small amount of water may be added to the component (A) such as any of the components (A-1) to (A-3), the components other than water may be prepared as concentrated solutions, and the components may be mixed at the site where the composition is to be used. The composition may also be prepared by transporting any of the components in such a concentrated state, that is, in a state not containing water, and adding water.

### <I-6. Properties of the Composition>

The composition of the present invention has a pH value of 10 or more, preferably 10.5 to 13.8, more preferably 11.0 to 13.6, and further preferably 11.3 to 13.3. The pH value can be measured using a pH meter, as described in detail below.

The composition of the present invention makes it possible to suppress damage to copper and copper alloys. As a result, it becomes possible to suppress a copper etching rate, which is evaluated by the method described in detail below in the Examples section, to 0.050 μm/min or less. More preferably, the copper etching rate as evaluated by the method described in detail below is 0.040 μm/min or less, further preferably 0.030 μm/min or less, and particularly preferably 0.020 μm/min or 0.015 μm/min or less.

The composition of the present invention can effectively remove a photoresist. As a result, it may become possible to set an L.P. (lifting point) value relating to a stripping rate, which is evaluated by the method described in detail below in the Examples section, to 100 seconds or less. More preferably, the L.P. value as evaluated by the method described in detail below is 90 seconds or less, further preferably 85 seconds or less, and particularly preferably 80 seconds or less or 75 seconds or less.

### <I-7. Use of the Composition>

There are no particular limitations on the temperature at which the composition is used to remove a photoresist, but a temperature of 10 to 70° C. is preferred, more preferably 20 to 65° C., and further preferably 25 to 60° C. Using the composition within this temperature range improves the removability of the photoresist, and also makes it easier to maintain the removal conditions of the photoresist by suppressing compositional changes in the composition.

There are no particular limitations on the processing time of the photoresist with the composition, but the processing time is preferably 20 to 600 seconds, more preferably 30 to 300 seconds, and may be 30 to 240 seconds. The processing time is the time the composition is in contact with the photoresist, and may be appropriately selected depending on various conditions such as the surface state of the photoresist to be removed, the concentration of the composition, the temperature, and the processing method.

There are no particular limitations on the method for bringing the composition of the present invention into contact with the photoresist. For example, methods such as a method wherein the composition of the present invention is brought into contact with the photoresist to be removed by dropping (single-wafer spin processing) or spraying or the like, or a method wherein the photoresist to be removed is immersed in the composition of the present invention, may be adopted. Either method may be adopted in the present invention.

### <II. Method for Removing Photoresist>

The photoresist removal method of the present invention includes a photoresist removal step in which the composition of the present invention is brought into contact with a photoresist for forming a copper-containing pattern. The method for removing the photoresist is described below.

The composition of the present invention can be suitably used, for example, when removing a photoresist for forming, on an insulating layer having copper wiring in at least a part thereof, a copper-containing circuit pattern that serves as a connection terminal portion of the copper wiring after the circuit pattern has been formed.

Herein, the “insulating layer having the copper wiring in at least a part thereof” is not particularly limited as long as the layer is an insulating layer having copper wiring on a surface or embedded inside. Examples include a silicon insulating layer of a printed wiring board, a package substrate for mounting a semiconductor element, a semiconductor wafer, and the like.

Further, the “copper-containing circuit pattern that serves as a connection terminal portion of the copper wiring” is, for example, a circuit pattern that serves as a connection terminal portion of the copper wiring in the insulating layer for making an electrical connection with other components.

In one embodiment of the present invention, the connection terminal portion is a connection terminal portion of copper wiring in a printed wiring board. Further, in one embodiment of the present invention, the connection terminal portion is a connection terminal portion of copper wiring in a package substrate for mounting a semiconductor element. In addition, in one embodiment of the present invention, the connection terminal portion is a connection terminal portion of copper wiring in a semiconductor element.

### <III. Method for Producing Printed Wiring and the Like>

The method for producing a printed wiring of the present invention includes a photoresist removal step in which the composition of the present invention is brought into contact with a photoresist for forming a copper-containing pattern. In addition to a printed wiring board, the composition of the present invention can also be suitably used in the photoresist removal step of a method for producing a semiconductor element and a semiconductor package.

For example, the composition of the present invention can be suitably used when, in the production process of a printed wiring board (for example, a package substrate for mounting a semiconductor element), removing a photoresist for forming, on an insulating layer having copper wiring in at least a part thereof, a copper-containing circuit pattern that serves as a connection terminal portion of the copper wiring after the circuit pattern has been formed.

In addition, the composition of the present invention can be suitably used in the production process of a semiconductor element when removing a photoresist for forming, on an insulating layer having copper wiring in at least a part thereof, a circuit pattern that includes copper and at least one selected from the group consisting of tin and a tin alloy, which serves as a connection terminal portion of the copper wiring, after the circuit pattern is formed.

The method for producing a printed wiring and the like preferably further includes a cleaning step of cleaning the photoresist-containing substrate that has been subjected to the photoresist removal step. In the cleaning step, it is preferred to clean the photoresist-containing substrate using, for example, sulfuric acid having a concentration of 40% by mass or less, water, and the like, and it is more preferred to clean with sulfuric acid and then clean with water, for example, pure water. The concentration of the sulfuric acid may be, for example, 30% by mass or less, 20% by mass or less, 10% by mass or less, 5% by mass or less, 2% by mass or less, 1% by mass or less, and the like. The temperature of the cleaning solution such as sulfuric acid or water is preferably 10 to 70° C., more preferably 15 to 50° C., and further preferably room temperature of about 20 to 30° C.

There are no particular limitations on the method for cleaning the photoresist-containing substrate with the cleaning solution, and for example, methods such as a method wherein the cleaning solution is brought into contact with the substrate to be cleaned by dropping (single-wafer spin processing) or spraying or the like, or a method wherein the substrate to be cleaned is immersed in the cleaning solution, may be adopted.

When the cleaning solution is sprayed onto the substrate in the cleaning step, the spraying time is, for example, 5 seconds to 5 minutes, preferably 10 seconds to 3 minutes, more preferably 15 seconds to 1 minute, and further preferably 20 seconds to 45 seconds. The spray pressure is, for example, 0.03 to 1.0 MPa, preferably 0.05 to 0.50 MPa, and further preferably 0.10 to 0.30 MPa or 0.10 to 0.20 MPa.

Examples of the photoresist used for a printed wiring board include a composition containing a binder polymer, a photopolymerizable monomer, a photopolymerization initiator, and other additives.

Examples of the binder polymer include those obtained by copolymerizing several types of vinyl monomers, such as a methacrylic acid ester, an acrylic acid ester, and styrene, with at least one of methacrylic acid and acrylic acid as an essential component.

Preferred photopolymerizable monomers include at least one of a methacrylic acid ester and an acrylic acid ester.

Examples of the photopolymerization initiator include at least one from the group consisting of benzophenone, 4,4′-diaminobenzophenone, 4,4′-bis(dimethylamino)benzophenone, 2-ethylanthraquinone, benzoin, benzoin methyl ether, 9-phenylacridine, benzyl dimethyl ketal, and benzyl diethyl ketal. Further, a bimolecular system consisting of a hexaarylbiimidazole and a hydrogen donor (2-mercaptobenzoxazal, N-phenylglycine) may also be used.

Examples of the other additives include a thermal polymerization initiator and a dye.

Examples of a preferred photoresist for use in a semiconductor element include a combination of a phenol-formaldehyde resin (collectively known as “novolac resins”) and a naphthoquinone diazide compound, which is a photosensitive component.

Examples of the resist arranged between the metal wires include a dry film resist, a liquid resist, and the like. Of these, the resist is preferably a dry film resist. There are no particular limitations on the dry film resist, but a dry film resist made of a photosensitive resin is preferred. Examples of the photosensitive resin include a negative photosensitive resin and a positive photosensitive resin.

Examples of the negative photosensitive resin include, but are not limited to, an azide-based photosensitive resin, a diazo-based photosensitive resin, an acetylenic low molecular weight photosensitive resins, an ethylenic low molecular weight photosensitive resin, an insolubilized polymer-based photosensitive resin, and a chromate-based photosensitive resin. These negative photosensitive resins may be used alone or in combination of two or more.

Examples of the positive photosensitive resin include, but are not limited to, a quinone diazide-based photosensitive resin, a solubilized polymer-based photosensitive resin, and the like. These positive photosensitive resins may be used alone or in combination of two or more.

Of these, the dry film resist is preferably formed from a negative photosensitive resin. Negative photosensitive resins undergo curing in the exposure process during pattern formation, and become insoluble in the developer, and so the exposed portions (the portions where the negative photosensitive resin has been cured) remain as the dry film resist. During exposure, curing tends to proceed particularly at the surface portion of the negative photosensitive resin that is exposed, and the surface portion of the resulting dry film resist can have a particularly dense structure. As a result, even if an attempt is made to remove the dry film resist using a composition, the composition may have difficulty penetrating into the interior of the dry film resist. Further, some compositions may not have sufficient resist removal ability, and removal of the dry film resist may not proceed. As a result, it may take a long time to remove the dry film resist.

In contrast, the composition of the present invention easily penetrates the dry film resist, allowing the dry film resist to be stripped off and removed quickly.

### EXAMPLES

(pH)

The pH of the aqueous compositions described in the examples and comparative examples was measured using a pH meter (D-53, manufactured by HORIBA, Ltd.).

### (Preparation of Sample for Evaluating Copper Corrosion Resistance)

A sample for evaluating copper corrosion resistance was prepared as follows. That is, the surface of a copper-clad laminate (CCL-HL832NX, manufactured by MITSUBISHI GAS CHEMICAL COMPANY, INC.) was electrolytically plated with copper (thickness: 35 μm) to obtain a sample for evaluating copper corrosion resistance.

### (Cleaning Properties)

The above sample for evaluating copper corrosion resistance cut into a 4 cm×4 cm square was brought into contact with the aqueous composition described in the examples and comparative examples by spraying the aqueous composition at a spray pressure of 0.15 MPa at 50° C. for 5 minutes. Next, the sample for evaluating copper corrosion resistance was cleaned using one of the following methods and then dried.

Water spraying: Sprayed with pure water at a spray pressure of 0.15 MPa at 25° C. for 30 seconds.
5% Sulfuric acid spraying: Sprayed with 5% by mass sulfuric acid at a spray pressure of 0.15 MPa at 25° C. for 30 seconds, and then cleaned with pure water. 5% Sulfuric acid immersion: Immersed in 5% by mass sulfuric acid at 25° C. for 30 seconds, and then cleaned with pure water.
20% Sulfuric acid spraying: Sprayed with 20% by mass sulfuric acid at a spray pressure of 0.15 MPa at 25° C. for 30 seconds, and then cleaned with pure water.

The N element of the obtained treated sample for evaluating copper corrosion resistance was measured using an X-ray photoelectron spectrometer (K-Alpha, manufactured by Thermo Fisher Scientific Inc.).

The cleaning properties were evaluated according to the following criteria, with the maximum peak intensity of the N element of the sample for evaluating copper corrosion resistance before treatment set at 100.

Cleanable (good): The maximum peak intensity of the N element of the sample for evaluating copper corrosion resistance after treatment was 120 or less.
Not cleanable (poor): The maximum peak intensity of the N element of the sample for evaluating copper corrosion resistance after treatment was more than 120.

### (Copper Corrosion Resistance (Cu E.R. (Etching Rate))

The sample for evaluating copper corrosion resistance cut into a 4 cm×4 cm square was brought into contact with the aqueous composition described in the examples and comparative examples by spraying the aqueous composition at a spray pressure of 0.15 MPa at 50° C. for 5 minutes. Next, the sample for evaluating copper corrosion resistance was cleaned with pure water, cleaned with 5% by mass sulfuric acid, then cleaned with pure water, after which the sample for evaluating copper corrosion resistance was thoroughly dried.

The value of the Cu E.R. (μm/min) was calculated as follows. Specifically, the mass of the sample for evaluating copper corrosion resistance before and after the above-described spraying treatment with the aqueous composition was measured, the etched thickness was calculated from the mass difference, the copper density (8.93 g/cm³), and the sample size (treated area [cm²]; it is noted that since the back side of the sample for evaluating copper corrosion resistance was protected with masking tape, the treated area is the area of the surface of the sample), and the etching amount per minute was determined based on the following expression (I).

$$Cu E . R . [ \frac{μ m}{min} ] = \frac{\begin{matrix}sample mass [ g ] \\ before treatment\end{matrix} - \begin{matrix}sample mass [ g ] \\ after treatment\end{matrix}}{t r eated area [ {cm}^{2} ] \times 8.93 [ \frac{g}{{cm}^{3}} ] \times t r e a tment time [ min ]} \times {10}^{4} \qquad ( I )$$

### Example 1

An aqueous composition was prepared by adding monoethanolamine (MEA) in an amount that would ultimately be 6% by mass (32 g of 75% MEA aqueous solution), tetramethylammonium hydroxide (TMAH) in an amount that would ultimately be 2% by mass (32 g of 25% TMAH aqueous solution), and ethylene glycol monophenyl ether (PhGE) in an amount that would ultimately be 2.25% by mass (9.0 g), 4-methylimidazole in an amount (0.36 g) that would ultimately be 0.09% by mass, and diethylene glycol monobutyl ether (DGBE) in an amount (5.4 g) that would ultimately be 1.35% by mass, respectively, to 321 g of pure water. The sample for evaluating copper corrosion resistance was treated using the resulting aqueous composition, and then cleaned by water spraying. The pH of the resulting aqueous composition was 13.3, the sample was cleanable (good), and the Cu E.R. was 0.01 μm/min.

The properties and evaluation results of the aqueous composition are shown in Table 1 below.

### Examples 2 to 12 and Comparative Examples 1 to 5

Aqueous compositions were prepared and evaluation tests were performed in the same manner as in Example 1, except that, as shown in Table 1 below, the type and amount of each component in the composition of Example 1 and the cleaning method of the sample for evaluating copper corrosion resistance were changed, and in some examples and comparative examples, additional components were added. The properties and evaluation results of the aqueous composition of each example and comparative example are shown in Table 1 below.

The tetramethylammonium bicarbonate (TMBC) added to the aqueous composition of Example 6 and the like can be generated as a degradation product of tetramethylammonium hydroxide (TMAH), and can reduce the stripping performance of the dry film resist by the aqueous composition. For this reason, in order to evaluate the stripping treatment by the aqueous composition when tetramethylammonium bicarbonate is generated by long-term use, the bicarbonate was added to the aqueous compositions of those examples.

TABLE 1

| | (A) Alkaline agent | | | | | | Components of composition [% by mass] | | | | |
|---|---|---|---|---|---|---|---|---|---|---|---|
| | (A-1) | | (A-2) | | (A-3) | | | | | | Solvent |
| | Compound | | Compound | | Compound | | | | Organic solvent | | Compound |
| | name | | name | | name | | (B) Azole compound | | Compound name | | name |
| | [% by | | [% by | | [% by | | Compound name | | [% by | | [% by |
| | mass] | | mass] | | mass] | | [% by mass] | | mass] | | mass] |
| Example 1 | MEA | 6 | TMAH | 2 | — | — | 4-methylimidazole | 0.09 | PhGE | 2.25 | DGBE |
| Example 2 | MEA | 5 | TMAH | 1 | — | — | 4-methylimidazole | 0.10 | PhGE | 2.5 | — |
| Example 3 | MEA | 5 | TMAH | 1 | — | — | 2-methylimidazole | 0.10 | PhGE | 2.5 | — |
| Example 4 | MEA | 5 | TMAH | 1 | — | — | 2-aminobenzimidazole | 0.10 | PhGE | 2.5 | — |
| Example 5 | MEA | 5 | TMAH | 1 | — | — | 3-methylpyrazole | 0.10 | PhGE | 2.5 | — |
| Example 6 | MEA | 6 | TMAH | 3 | KOH | 0.3 | 4-methylimidazole | 0.09 | EGPE | 2 | — |
| Example 7 | MEA | 6 | TMAH | 3 | KOH | 0.3 | 4-methylimidazole | 0.09 | EGPE | 2 | — |
| Example 8 | MEA | 6 | TMAH | 3 | KOH | 0.3 | 4-methylimidazole | 0.09 | EGPE | 2 | — |
| Example 9 | MEA | 6 | TMAH | 3 | KOH | 0.3 | 5-methylbenzimidazole | 0.03 | EGPE | 2 | — |
| Example 10 | MEA | 6 | TMAH | 3 | KOH | 0.3 | 3-methylpyrazole | 0.20 | EGPE | 2 | — |
| Example 11 | MEA | 6 | TMAH | 3 | KOH | 0.3 | 3-methylpyrazole | 0.20 | EGPE | 2 | — |
| Example 12 | MEA | 6 | TMAH | 3 | KOH | 0.3 | 3-methylpyrazole | 0.20 | EGPE | 2 | — |
| Comparative | MEA | 6 | TMAH | 3 | KOH | 0.3 | tolyltriazole | 0.09 | EGPE | 2 | — |
| Example 1 | | | | | | | | | | | |
| Comparative | MEA | 6 | TMAH | 3 | KOH | 0.3 | 2-mercapto-1- | 0.03 | EGPE | 2 | — |
| Example 2 | | | | | | | methylimidazole | | | | |
| Comparative | MEA | 6 | TMAH | 3 | KOH | 0.3 | 2-mercapto-5- | 0.03 | EGPE | 2 | — |
| Example 3 | | | | | | | methylbenzimidazole | | | | |
| Comparative | MEA | 6 | TMAH | 3 | KOH | 0.3 | 2-benzimidazolethiol | 0.09 | EGPE | 2 | — |
| Example 4 | | | | | | | | | | | |
| Comparative | MEA | 8 | TMAH | 8 | — | — | 1,2,4-triazole | 0.16 | PhGE | 4 | — |
| Example 5 | | | | | | | | | | | |

| | Components of composition [% by mass] | | | | | | | | | |
|---|---|---|---|---|---|---|---|---|---|---|
| | Solvent | | | | | | | | | |
| | Compound | Ammonium salt | | Aging agent | | | | | | |
| | name | Compound name | | Compound name | | Evaluation results | | | | |
| | [% by | [% by | | [% by | | | | | Cleaning | Cu E.R. |
| | mass] | mass] | | mass] | | pH | Cleaning method | | properties | [μm/min] |
| Example 1 | 1.35 | — | — | — | — | 13.3 | water | spraying | good | 0.010 |
| Example 2 | — | — | — | — | — | 13.0 | 20% sulfuric | spraying | good | 0.008 |
| | | | | | | | acid | | | |
| Example 3 | — | — | — | — | — | 13.0 | 20% sulfuric | spraying | good | 0.020 |
| | | | | | | | acid | | | |
| Example 4 | — | — | — | — | — | 13.0 | 20% sulfuric | spraying | good | 0.004 |
| | | | | | | | acid | | | |
| Example 5 | — | — | — | — | — | 13.0 | 20% sulfuric | spraying | good | 0.002 |
| | | | | | | | acid | | | |
| Example 6 | — | ammonium | 1.5 | TMBC | 7 | 11.3 | water | spraying | good | 0.040 |
| | | benzoate | | | | | | | | |
| Example 7 | — | ammonium | 1.5 | TMBC | 7 | 11.3 | 5% sulfuric | immersion | good | 0.040 |
| | | benzoate | | | | | acid | | | |
| Example 8 | — | ammonium | 1.5 | TMBC | 7 | 11.3 | 5% sulfuric | spraying | good | 0.040 |
| | | benzoate | | | | | acid | | | |
| Example 9 | — | ammonium | 1.5 | TMBC | 7 | 11.3 | 5% sulfuric | immersion | good | 0.005 |
| | | benzoate | | | | | acid | | | |
| Example 10 | — | ammonium | 1.5 | TMBC | 7 | 11.3 | water | spraying | good | 0.004 |
| | | benzoate | | | | | | | | |
| Example 11 | — | ammonium | 1.5 | TMBC | 7 | 11.3 | 5% sulfuric | immersion | good | 0.004 |
| | | benzoate | | | | | acid | | | |
| Example 12 | — | ammonium | 1.5 | TMBC | 7 | 11.3 | 5% sulfuric | spraying | good | 0.004 |
| | | benzoate | | | | | acid | | | |
| Comparative | — | ammonium | 1.5 | TMBC | 7 | 11.3 | 5% sulfuric | spraying | poor | 0.007 |
| Example 1 | | benzoate | | | | | acid | | | |
| Comparative | — | ammonium | 1.5 | TMBC | 7 | 11.3 | 5% sulfuric | spraying | poor | 0.010 |
| Example 2 | | benzoate | | | | | acid | | | |
| Comparative | — | ammonium | 1.5 | TMBC | 7 | 11.3 | 5% sulfuric | spraying | poor | 0.003 |
| Example 3 | | benzoate | | | | | acid | | | |
| Comparative | — | ammonium | 1.5 | TMBC | 7 | 11.3 | 5% sulfuric | spraying | poor | 0.006 |
| Example 4 | | benzoate | | | | | acid | | | |
| Comparative | — | — | — | TMBC | 7 | 14.1 | 5% sulfuric | spraying | good | 0.070 |
| Example 5 | | | | | | | acid | | | |

(Abbreviations in the table)
(A) Alkaline agent
MEA: monoethanolamine
TMAH: tetramethylammonium hydroxide
Organic solvent
PhGE: phenyl glycol = ethylene glycol monophenyl ether
EGPE: ethylene glycol monopropyl ether
Solvent/Aging agent
DGBE: diethylene glycol monobutyl ether
TMBC: tetramethylammonium bicarbonate
Evaluation results
L.P.: lifting point
E.R.: etching rate

As is clear from the above results, the aqueous compositions of the examples containing a certain azole compound showed better cleaning results than the aqueous compositions of the comparative examples, that is, it was confirmed that the amount of N element remaining on the surface of the copper-containing sample could be suppressed. Further, in the examples, the Cu E.R. (etching rate) value was lower than in the comparative examples, and the copper corrosion resistance of the composition was excellent.

Although not shown in Table 1, supplementary evaluation tests were also conducted on some of the examples as follows, and the evaluation methods and results are shown below.

### (Preparation of Sample for Evaluating Stripping Properties)

A sample for evaluating stripping properties was prepared as follows. First, a copper-clad laminate (CCL-HL832NS (MT-FL) 0.1 mmtC/C, manufactured by MITSUBISHI GAS CHEMICAL COMPANY, INC.) was chemically plated with copper to form a thin copper film (thickness: 1.0 μm). A dry film resist (RD-3025, manufactured by Showa Denko K.K., thickness: 25 μm) was attached to the surface of the thin copper film, a circuit mask pattern was formed thereon, and exposure and development were carried out. The dry film resist was exposed and developed to form a circuit pattern opening, which was then electrolytically plated with copper (thickness: 17 μm) to obtain a sample for evaluating stripping properties. The pattern of the dry film resist formed on the sample for evaluating stripping properties was a pattern of dots of 100 to 300 μm in diameter.

### (Stripping Properties)

The aqueous composition used in Examples 6 to 8 (hereinafter, “aqueous composition A”), the aqueous composition used in Examples 10 to 12 (hereinafter, “aqueous composition B”), and the aqueous composition used in Comparative Example 5 were each sprayed onto the above-described samples for evaluating stripping properties at a spray pressure of 0.15 MPa at 50° C. for 3 minutes to bring the sample into contact with the aqueous composition. The samples were then cleaned with pure water, cleaned with 5% by mass sulfuric acid, cleaned again with pure water, and then thoroughly dried.

The stripping properties was evaluated as follows. Using an optical microscope (MX-61L, manufactured by Olympus Corporation, objective lens 50×), residues of the dry film resist on the samples for evaluating stripping properties that had been sprayed with the aqueous composition as described above were checked, and evaluated according to the following criteria.

Particularly good: All samples had 2 or less residues of dry film resist 100 to 300 μm in diameter.
Good: All samples had 110 or less residues of dry film resist 100 to 300 μm in diameter.
Poor: Some samples had more than 110 residues of dry film resist 100 to 300 μm in diameter.

The results of the stripping properties evaluation test were as follows.

### Aqueous Composition A

### Good

One dry film resist residue of 300 μm in diameter.
Seven dry film resist residues of 250 μm in diameter.
No dry film resist residues of 200 μm in diameter.
Seven dry film resist residues of 150 μm in diameter.
No dry film resist residues of 100 μm in diameter.

### Aqueous Composition B

### Particularly Good

No dry film resist residues of 300 μm in diameter.
No dry film resist residues of 250 μm in diameter.
One film resist residue of 200 μm in diameter.
No dry film resist residues of 150 μm in diameter.
No dry film resist residues of 100 μm in diameter.

### Aqueous Composition of Comparative Example 5

### Poor

No dry film resist residues of 300 μm in diameter.
No dry film resist residues of 250 μm in diameter.
No dry film resist residues of 200 μm in diameter.
No dry film resist residues of 150 μm in diameter.
113 dry film resist residues of 100 μm in diameter.

### (Stripping Rate (L.P. (Lifting Point)))

The aqueous composition A of the examples, the aqueous composition B of the examples, and the aqueous composition of Comparative Example 5 were each brought into contact with the above-described sample for evaluating stripping properties by spraying at a spray pressure of 0.15 MPa at 50° C.

Then, the time from when the aqueous composition was sprayed to when the dry film resist was completely stripped from the substrate of the sample for evaluating stripping properties was measured, and taken as the L.P. (seconds). In measuring the L.P., the dots that were 250 μm in diameter in the pattern formed on the sample for evaluating stripping properties were visually observed, and the point at which the dry film resist had been removed was taken as the time.

The results of the stripping rate evaluation test were as follows.

Aqueous composition A: 90 (seconds)
Aqueous composition B: 90 (seconds)
Aqueous composition of Comparative Example 5:110 (seconds)

As is clear from the results of the supplementary tests described above, the aqueous compositions of the examples containing a specific azole compound were superior in terms of suppressing the generation of resist residues compared to the aqueous compositions of the comparative examples, and the time indicated by the L.P. (lifting point) value was shorter, confirming that the photoresist can be stripped quickly.

1. A composition for removing a photoresist, which is for forming a copper-containing pattern, after the pattern has been formed, comprising:
an alkaline agent; and
an azole compound, wherein
the alkaline agent is one or more selected from the group consisting of an alkanolamine, a quaternary ammonium hydroxide, and an inorganic alkali,
the azole compound is one or more selected from the group consisting of compounds represented by the following formulas (1) to (3), and
the composition has a pH of 10 or higher, 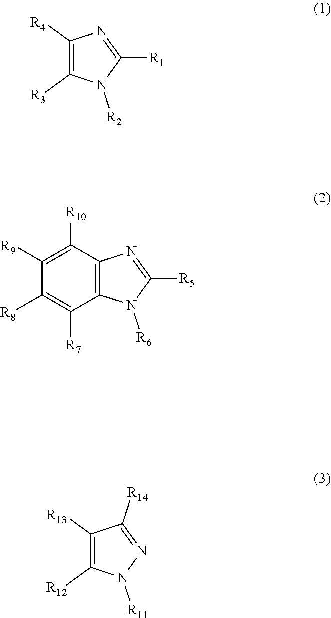
wherein R₁ to R₁₄ each independently represent a hydrogen atom, an optionally substituted alkyl group having 1 or more and 7 or less carbon atoms, or an optionally substituted amino group.

2. The composition according to claim 1, wherein an etching rate of copper is less than 0.05 μm/min.

3. The composition according to claim 1, wherein the azole compound comprises at least any of 4-methylimidazole, 2-methylimidazole, 5-methylbenzimidazole, 2-aminobenzimidazole, and 3-methylpyrazole.

4. The composition according to claim 1, further comprising an organic solvent.

5. The composition according to claim 1, wherein the composition comprises, based on a total amount of the composition, 3.0 to 50% by mass of the alkaline agent and 0.001 to 1.0% by mass of the azole compound.

6. The composition according to claim 1, wherein the composition is water-soluble.

7. The composition according to claim 1, wherein the composition is free from a thiol compound.

8. The composition according to claim 1, wherein the pattern is a circuit pattern that serves as a connection terminal portion of copper wiring formed on an insulating layer having the copper wiring in at least a part thereof.

9. A method for removing a photoresist, comprising a photoresist removal step of bringing the composition according to claim 1 into contact with a photoresist for forming a copper-containing pattern.

10. The method for removing a photoresist according to claim 9, wherein the pattern is a circuit pattern that serves as a connection terminal portion of copper wiring formed on an insulating layer having the copper wiring in at least a part thereof.

11. A method for producing a printed wiring board, a semiconductor element, or a semiconductor package, comprising a photoresist removal step of bringing the composition according to claim 1 into contact with a photoresist for forming a copper-containing pattern.

12. The method for producing a printed wiring board, a semiconductor element, or a semiconductor package according to claim 11, further comprising, after the photoresist removal step, a cleaning step of cleaning a photoresist-containing substrate that contained the photoresist.

13. The method for producing a printed wiring board, a semiconductor element, or a semiconductor package according to claim 12, wherein in the cleaning step, the photoresist-containing substrate is cleaned using sulfuric acid having a concentration of 40% by mass or less and/or water.

14. The method for producing a printed wiring board, a semiconductor element, or a semiconductor package according to claim 11, wherein the pattern is a circuit pattern that serves as a connection terminal portion of copper wiring formed on an insulating layer having the copper wiring in at least a part thereof.
